(19) United States
(12) Patent Application Publication
(10) Pub. No.: US 2024/0026105 A1
(43) Pub. Date: Jan. 25, 2024

(54) METHOD FOR FORMING A RESIN LAYER AND AN APPARATUS FOR FORMING THE RESIN LAYER USED THEREIN

(71) Applicant: Samsung Display Co., LTD., Yongin-si (KR)

(72) Inventors: Jungwoong BYUN, Osan-si (KR); DOHUN LEE, Seoul (KR); CHEONG-WAN MIN, Hwaseong-si (KR); JAIHYUK CHOI, Hwaseong-si (KR)

(73) Assignee: Samsung Display Co., LTD., Yongin-si (KR)

(21) Appl. No.: 18/191,144

(22) Filed: Mar. 28, 2023

(30) Foreign Application Priority Data
Jul. 22, 2022 (KR) 10-2022-0090942

(51) Int. Cl. C08J 7/12; H10K 59/80; H10K 59/12

(52) U.S. Cl. CPC C08J 7/123; H10K 59/873; H10K 59/1201

(57) ABSTRACT

A method for forming a resin layer, the method including selectively applying an ultraviolet ray curable material that reacts to ultraviolet rays on a target substrate, selectively curing a preliminary resin layer by irradiating at least a portion of an entire area of the preliminary resin layer formed of the ultraviolet ray curable material with first ultraviolet rays whose shape and amount of light are adjusted, and completely curing the preliminary resin layer by irradiating second ultraviolet rays having a different amount of light from the first ultraviolet rays whose shape and amount of light are adjusted.

### CROSS-REFERENCE TO RELATED APPLICATION(S)

This application claims priority to and benefits of Korean Patent Application No. 10-2022-0090942 under 35 U.S.C. § 119, filed on Jul. 22, 2022 in the Korean Intellectual Property Office, the entire contents of which are incorporated herein by reference.

### BACKGROUND

### 1. Technical Field

Embodiments relate to a method for forming a resin layer and an apparatus for forming the resin layer.

### 2. Description of the Related Art

An ultraviolet ray curable material cured by reacting with ultraviolet rays in a display device process or other processes may be used for various purposes. For example, the ultraviolet ray curable material may be used in a bonding process (e.g., a bonding process between a display panel and a cover window), a coating process (e.g., a thin film encapsulation layer forming process), and the like.

A resin layer may be formed using the ultraviolet ray curable material in the bonding process, the coating process, and the like. In order to form the resin layer, the ultraviolet ray curable material may be applied on a target substrate, and the applied ultraviolet ray curable material may be irradiated with ultraviolet rays to collectively cure the ultraviolet ray curable material. For example, an inkjet, dispenser, or screen printing method may be used to apply the ultraviolet ray curable material.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a method for forming a resin layer including an ultraviolet curable material that reacts to ultraviolet rays.

Embodiments provide an apparatus for forming the resin layer used in the method for forming the resin layer.

A method for forming a resin layer according to embodiments of the disclosure may include selectively applying an ultraviolet ray curable material that reacts to ultraviolet rays on a target substrate, selectively curing a preliminary resin layer by irradiating at least a portion of an entire area of the preliminary resin layer formed of the ultraviolet ray curable material with first ultraviolet rays whose shape and amount of light are adjusted, and completely curing the preliminary resin layer by irradiating second ultraviolet rays having a different amount of light from the first ultraviolet rays whose shape and amount of light are adjusted.

In an embodiment, the ultraviolet ray curable material may include an optical clear resin (“OCR”).

In an embodiment, the preliminary resin layer may be divided into a central area and a peripheral area adjacent to the central area. In the selectively curing of the preliminary resin layer, at least a portion of the peripheral area of the preliminary resin layer may be selectively cured.

In an embodiment, the method may further include generating data of a digital ultraviolet ray image of the first ultraviolet ray, first data of an irradiation time of the first ultraviolet rays, and second data of the amount of light of the first ultraviolet rays before selectively curing the preliminary resin layer.

In an embodiment, in the selectively curing of the preliminary resin layer, the preliminary resin layer may be selectively cured by adjusting the shape and amount of light of the first ultraviolet rays based on the data, the first data, and the second data.

In an embodiment, at least a portion of the digital ultraviolet ray image may include at least one of a 1-bit pattern shape, an 8-bit gray scale shape, a comb shape, a random dot shape, and a mosaic shape.

In an embodiment, in the selectively curing of the preliminary resin layer, a portion of the preliminary resin layer corresponding to the at least the portion of the digital ultraviolet ray image may be cured.

In an embodiment, the method may further include heating the target substrate and the preliminary resin layer after selectively curing the preliminary resin layer.

In an embodiment, in the selectively applying the ultraviolet ray curable material, at least one of inkjet, dispenser, and screen printing may be used.

In an embodiment, the amount of light of the second ultraviolet rays may be greater than the amount of light of the first ultraviolet rays whose shape and amount of light are adjusted.

In an embodiment, the target substrate may be a substrate for a display device.

An apparatus for forming a resin layer according to embodiments of the disclosure may include a transfer stage that transfers a target substrate, a printing part that selectively applies an ultraviolet ray curable material that reacts to ultraviolet rays on the target substrate, a first light source that emits first ultraviolet rays, a digital light source processing part that adjusts shape an amount of light of the first ultraviolet rays and selectively cures a preliminary resin layer by irradiating at least a portion of an entire area of the preliminary resin layer formed of the ultraviolet ray curable material with the first ultraviolet rays whose shape and amount of light are adjusted, and a second light source that irradiates the preliminary resin layer with second ultraviolet rays having a different amount of light from the first ultraviolet rays whose shape and amount of light are adjusted.

In an embodiment, the printing part may include at least one of an inkjet printing apparatus, a dispenser apparatus and a screen printing apparatus.

In an embodiment, the ultraviolet ray curable material may include an optical clear resin.

In an embodiment, the digital light source processing part may include a mirror that reflects the first ultraviolet rays emitted from the first light source, a first lens that transmits the first ultraviolet rays reflected by the mirror, a digital light source processing element that selectively reflects the first ultraviolet rays transmitted by the first lens, and a second lens that transmits the first ultraviolet rays whose shape and amount of light area adjusted by the digital light source processing element.

In an embodiment, the first lens may be an illumination lens and the second lens may be a projection lens.

In an embodiment, the amount of light of the second ultraviolet rays may be greater than the amount of light of the first ultraviolet rays whose shape and amount of light are adjusted.

In an embodiment, the apparatus for forming a resin layer may further include a transfer stage part that generates a position pulse signal, an external trigger part that generates a trigger signal based on the position pulse signal, an operation part that generates data of a digital ultraviolet ray image of the first ultraviolet rays and provides the data to the digital light source processing part, and generates first data of an irradiation time of the first ultraviolet rays and second data of the amount of light of the first ultraviolet rays, and a light source controller that converts the trigger signal, the first data, and the second data into current impulses and provides the current impulses to the first light source.

In an embodiment, the digital light source processing part may selectively cure the preliminary resin layer by adjusting the shape and amount of light of the first ultraviolet rays based on the data, the first data, and the second data.

In an embodiment, at least a portion of the digital ultraviolet ray image may include at least one of a 1-bit pattern shape, an 8-bit gray scale shape, a comb shape, a random dot shape, and a mosaic shape.

In an embodiment, the digital light source processing part may cure a portion of the preliminary resin layer corresponding to the at least the portion of the digital ultraviolet image.

In an embodiment, the target substrate may be a substrate for a display device.

According to an embodiment of the disclosure, both selective application of an ultraviolet ray curable material on a target substrate and selective curing of a preliminary resin layer including the ultraviolet ray curable material applied on the target substrate may be applied. For example, selective curing of the preliminary resin layer may be added before completely curing the preliminary resin layer. Accordingly, a profile of a cross section of the resin layer formed by curing the preliminary resin layer including the ultraviolet ray curable material may be adjusted. A uniformity of the resin layer may be controlled, and unevenness of the resin layer may be improved.

### BRIEF DESCRIPTION OF THE DRAWINGS

Illustrative, non-limiting embodiments will be more clearly understood from the following detailed description in conjunction with the accompanying drawings.

FIG. 1 is a view schematically illustrating an apparatus for forming a resin layer according to an embodiment.

FIG. 2 is a view schematically illustrating an example of a digital ultraviolet image of ultraviolet rays emitted from a digital light source processing module of FIG. 1.

FIG. 3 is a view schematically illustrating another example of a digital ultraviolet image of ultraviolet rays emitted from a digital light source processing module of FIG. 1.

FIG. 4 is a flowchart schematically illustrating a method of forming a resin layer according to an embodiment.

FIGS. 5, 6, 7, 8, 9, 10, 11, and 12 are cross-sectional views schematically illustrating an example of a method of forming the resin layer of FIG. 4.

FIGS. 13 and 14 are cross-sectional views schematically illustrating another example of a method of forming the resin layer of FIG. 4.

### DETAILED DESCRIPTION OF THE EMBODIMENTS

Hereinafter, a method for forming a resin layer and an apparatus for forming the resin layer used therein according to embodiments of the disclosure will be explained in detail with reference to the accompanying drawings. The same reference numerals are used for the same components in the drawings, and redundant descriptions of the same components will be omitted.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within±30%, 20%, 10%, 5% of the stated value.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

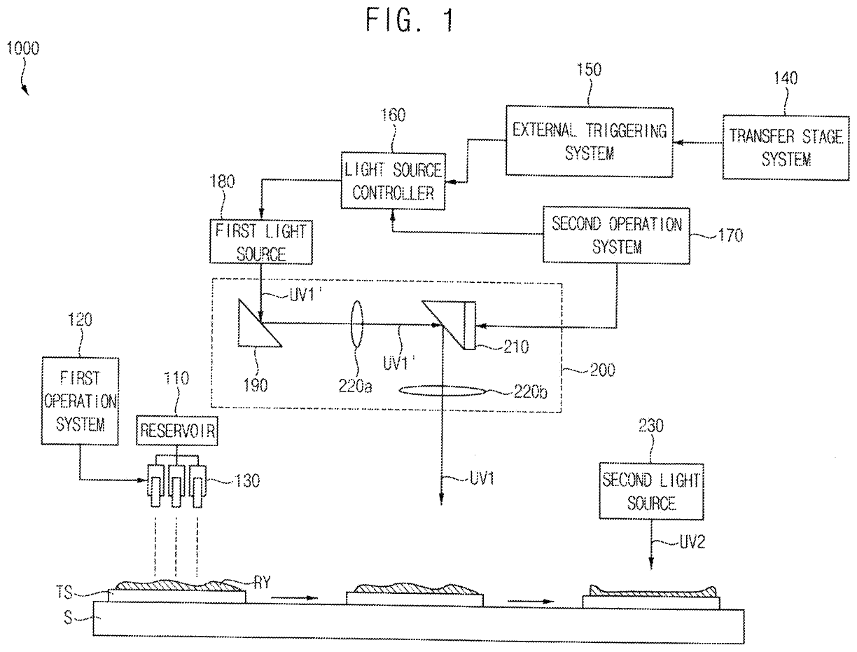

FIG. 1 is a view schematically illustrating an apparatus for forming a resin layer according to an embodiment.

Referring to FIG. 1, an apparatus for forming a resin layer 1000 according to an embodiment of the disclosure may include a transfer stage S, a reservoir 110, a first operation system (part) 120, a printing system (part) 130, a transfer stage system (part) 140, an external trigger system (part) 150, a light source controller 160, a second operation system (part) 170, a first light source 180, a digital light source processing module (part) 200 and a second light source 230.

A target substrate TS may be seated on the transfer stage S. The transfer stage S may transfer the target substrate TS. In an embodiment, the target substrate TS may be a substrate for a display device. The target substrate TS may correspond to a display panel excluding a thin film encapsulation layer (e.g., a display panel PNL of FIG. 12) or the display panel including the thin film encapsulation layer. However, the disclosure is not limited thereto. For example, the target substrate TS may be a substrate used in another field.

An ultraviolet ray (“UV”) curable material that reacts to ultraviolet rays may be stored in the reservoir 110. In an embodiment, the ultraviolet ray curable material may include an optical clear resin (“OCR”). However, the type of the ultraviolet ray curable material is not limited thereto, and the ultraviolet ray curable material may include various materials that react to ultraviolet rays.

The first operation system 120 may generate data of a digital print image. The data of the digital print image generated through the first operation system 120 may be provided to the printing system 130. An application position of ultraviolet ray curable material, an application amount of the ultraviolet ray curable material, and the like may be determined according to the digital print image.

The printing system 130 may receive the ultraviolet ray curable material stored in the reservoir 110. The printing system 130 may selectively apply the ultraviolet ray curable material provided from the reservoir 110 on the target substrate TS based on the data of the digital print image. For example, the printing system 130 may selectively apply the ultraviolet ray curable material to a desired position in a desired amount. Accordingly, a preliminary resin layer RY including the ultraviolet ray curable material may be formed on the target substrate TS.

In an embodiment, the printing system 130 may include an inkjet printing apparatus having nozzles. In another embodiment, the printing system 130 may include at least one of a dispenser apparatus and a screen printing apparatus. However, the configuration of the disclosure is not limited thereto, and the printing system 130 may include various application apparatuses.

The transfer stage system 140 may provide a position pulse signal to the external trigger system 150. For example, the transfer stage system 140 may provide the position pulse signal to the external trigger system 150 as a low voltage differential signal (“LVDS”). As the transfer stage system 140 provides the position pulse signal to the external trigger system 150, the transfer stage S may transfer the target substrate TS.

The external trigger system 150 may generate a trigger signal based on the position pulse signal. The trigger signal generated through the external trigger system 150 may be provided to the light source controller 160.

The second operation system 170 may generate first data of the irradiation time of first ultraviolet rays UV1 and second data of the amount of light of the first ultraviolet rays UV1. The first data of the irradiation time of the first ultraviolet rays UV1 and the second data of the amount of light of the first ultraviolet rays UV1 generated through the second operating system 170 may be provided to the light source controller 160.

The second operation system 170 may generate data of a digital ultraviolet image. An irradiation position of the first ultraviolet rays UV1 may be determined according to the shape of the digital ultraviolet image. For example, a cross-sectional shape of the preliminary resin layer RY may be determined according to the shape of the digital image.

The data for the digital ultraviolet image generated through the second operation system 170 may be provided to the digital light source processing module 200 (e.g., a digital light source processing element 210). A detailed description of the digital ultraviolet image will be described later.

The light source controller 160 may convert the trigger signal provided from the external trigger system 150 and the first data and the second data provided from the second operation system 170 into current impulse. The light source controller 160 may provide the current impulse to the first light source 180.

The first light source 180 may emit first ultraviolet rays UV1′ based on the current impulse. The first ultraviolet rays UV1′ immediately after being emitted from the first light source 180 may have a constant amount of light. The first ultraviolet rays UV1′ emitted from the first light source 180 may be irradiated to the digital light source processing module 200. For example, the wavelength of the first ultraviolet UV1′ may be about 385 nm to about 415 nm. However, the wavelength of the first ultraviolet UV1′ is not limited thereto.

The digital light source processing module 200 may adjust the shape and amount of the first ultraviolet rays UV1′ emitted from the first light source 180, and may selectively cure the preliminary resin layer RY by irradiating the first ultraviolet rays UV1 whose shape and amount of light are adjusted to at least a portion of an entire area of the preliminary resin layer RY formed of the ultraviolet ray curable material.

Specifically, the digital light source processing module 200 may selectively cure the preliminary resin layer RY by adjusting the shape and amount of the first ultraviolet rays UV1′ based on the data of the digital ultraviolet image of the first ultraviolet rays UV1, the first data of the irradiation time of the first ultraviolet rays UV1, and the second data of the amount of light of the first ultraviolet rays UV1.

Hereinafter, components of the digital light source processing module 200 will be described in detail.

The digital light source processing module 200 may include a mirror 190, a first lens 220a, a digital light source processing element 210, and a second lens 220b.

The mirror 190 may reflect the first ultraviolet rays UV1′ emitted from the first light source 180. The mirror 190 may serve to reflect the first ultraviolet rays UV1′ emitted from the first light source 180 and finally provide the first ultraviolet rays UV1′ to the digital light source processing element 210.

The first lens 220a may transmit the first ultraviolet rays UV1′ reflected by the mirror 190. In an embodiment, the first lens 220a may be an illumination lens. However, the type of the first lens 220a is not limited thereto.

The digital light processing (“DLP”) element 210 may include digital mirrors or micro mirrors manufactured by micro electro mechanical system (“MEMS”) technology.

The digital light source processing element 210 may selectively reflect the first ultraviolet rays UV1′ transmitted from the first lens 220a. Specifically, the digital light source processing element 210 may digitally process the first ultraviolet rays UV1′ transmitted through the first lens 220a based on the data of the digital ultraviolet image of the first ultraviolet rays UV1, the first data of the irradiation time of the first ultraviolet rays UV1, and the second data of the amount of light of the first ultraviolet rays UV1.

For example, a portion of the first ultraviolet rays UV1′ toward the digital light source processing element 210 may be reflected, and other portions of the first ultraviolet rays UV1′ may be extinguished. Accordingly, the first ultraviolet rays UV1 reflected by the digital light source processing element 210 may be ultraviolet rays whose shape and amount of light are adjusted.

The second lens 220b may transmit the first ultraviolet rays UV1 whose shape and amount of light are adjusted by the digital light source processing element 210. In an embodiment, the second lens 220b may be a projection lens. However, the type of the second lens 220b is not limited thereto. The first ultraviolet rays UV1 transmitted through the second lens 220b may be irradiated to the preliminary resin layer RY formed on the target substrate TS. Accordingly, the preliminary resin layer RY may be selectively cured.

A heater (not shown) may be disposed around the transfer stage S. The heater may heat the target substrate TS and the preliminary resin layer RY. As the preliminary resin layer RY is heated, the preliminary resin layer RY may be subjected to an aging process. In case that the preliminary resin layer RY is subjected to the aging process, the viscosity of the preliminary resin layer RY may be lowered and planarization may be performed on the preliminary resin layer RY.

The second light source 230 may emit the second ultraviolet rays UV2. In an embodiment, the amount of light of the second ultraviolet rays UV2 may be greater than the amount of light of the first ultraviolet rays UV1 whose shape and amount of light are adjusted by the digital light source processing element 210. For example, the wavelength of the second ultraviolet rays UV2 may be about 385 nm to about 415 nm. For example, the wavelength of the second ultraviolet rays UV2 may be similar to the wavelengths of the first ultraviolet rays UV1′ and UV1. However, the wavelength of the second ultraviolet rays UV2 is not limited thereto. The second ultraviolet rays UV2 emitted from the second light source 230 may be irradiated to the preliminary resin layer RY. Accordingly, the preliminary resin layer RY may be completely cured.

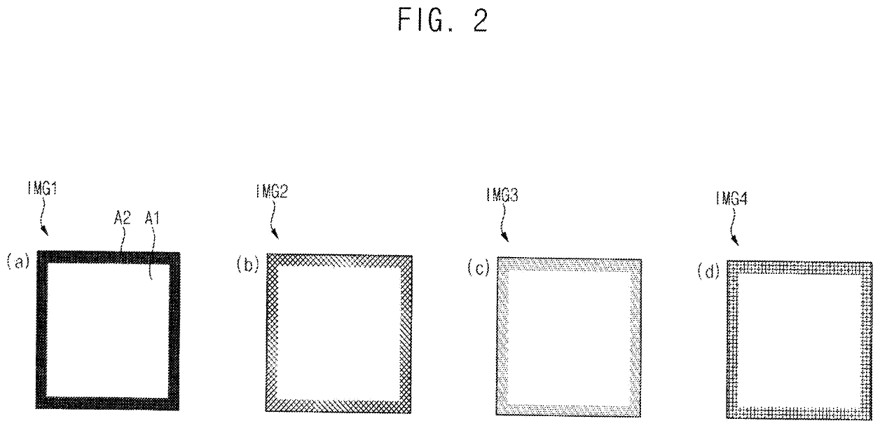

FIG. 2 is a view schematically illustrating an example of a digital ultraviolet image of ultraviolet rays emitted from a digital light source processing module of FIG. 1.

Referring to FIGS. 1 and 2, as described above, the digital light source processing module 200 may receive the data for the digital ultraviolet image of the first ultraviolet rays UV1.

In an embodiment, at least a portion of the digital ultraviolet image may have at least one of a 1-bit pattern shape, an 8-bit gray scale shape, a comb shape, a random dot shape, and a mosaic shape.

However, the disclosure is not limited thereto, and at least a portion of the digital ultraviolet image may have various shapes. Accordingly, a portion of the preliminary resin layer RY corresponding to the at least the portion of the digital ultraviolet image may be cured. For example, the irradiation position of the first ultraviolet rays UV1 may be determined according to the form of the digital ultraviolet image.

For example, the digital ultraviolet image may include any of a first ultraviolet ray image IMG1 corresponding to (a) of FIG. 2, a second ultraviolet image ray IMG2 corresponding to (b) of FIG. 2, a third ultraviolet ray image IMG3 corresponding to (c) of FIG. 2, and a fourth ultraviolet image IMG4 corresponding to (d) of FIG. 2.

For example, each of the first, second, third, and fourth ultraviolet ray images IMG1, IMG2, IMG3, and IMG4 may include a first area A1 and a second area A2. The second area A2 may surround the first area A1. The second area A2 of each of the first, second, third, and fourth ultraviolet images IMG1, IMG2, IMG3, and IMG4 may have a specific shape.

The second area A2 of the first ultraviolet ray image IMG1 may have an 8-bit gray scale shape. The second area A2 of the second ultraviolet ray image IMG2 may have a comb shape. The second area A2 of the third ultraviolet ray image IMG3 may have a random dot shape. The second area A2 of the fourth ultraviolet ray image IMG4 may have a mosaic shape.

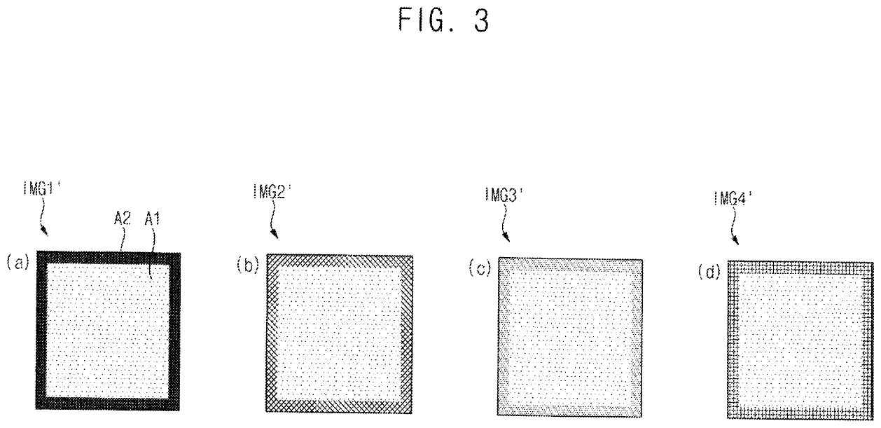

FIG. 3 is a view schematically illustrating another example of a digital ultraviolet image of ultraviolet rays emitted from a digital light source processing module of FIG. 1.

Hereinafter, a description overlapping with the digital ultraviolet image described with reference to FIGS. 1 and 2 will be omitted or simplified.

Referring to FIGS. 1 and 3, as described above, the digital light source processing module 200 may receive the data for the digital ultraviolet image of the first ultraviolet rays UV1.

For example, the digital ultraviolet image may include any of a first ultraviolet ray image IMG1′ corresponding to (a) of FIG. 3, a second ultraviolet image ray IMG2′ corresponding to (b) of FIG. 3, a third ultraviolet ray image IMG3′ corresponding to (c) of FIG. 3, and a fourth ultraviolet image IMG4′ corresponding to (d) of FIG. 3.

For example, the shape of the second area A2 of each of the first, second, third, and fourth ultraviolet ray images IMG1′, IMG2′, IMG3′, and IMG4′ illustrated in FIG. 3 may be the same as the shape of the second area A2 of each of the first, second, third, and fourth ultraviolet ray images IMG1, IMG2, IMG3, and IMG4 illustrated in FIG. 2.

For example, the first area A1 of each of the first, second, third, and fourth ultraviolet ray images IMG1′, IMG2′, IMG3′, and IMG4′ may have a random dot shape. However, the disclosure is not limited thereto, and the first area A1 of each of the first, second, third, and fourth ultraviolet ray images IMG1′, IMG2′, IMG3′, and IMG4′ may have various shapes.

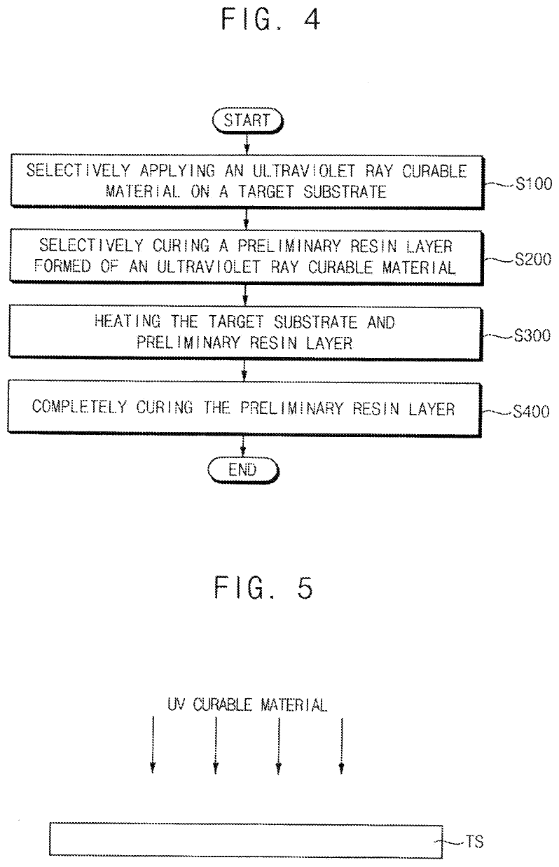

FIG. 4 is a flowchart schematically illustrating a method of forming a resin layer according to an embodiment. FIGS. 5, 6, 7, 8, 9, 10, 11, and 12 are cross-sectional views schematically illustrating an example of a method of forming the resin layer of FIG. 4. For example, the apparatus for forming the resin layer 1000 illustrated in FIG. 1 may be used in the method of forming the resin layer.

Referring to FIG. 4, the method of forming the resin layer according to an embodiment of the disclosure may include selectively applying the ultraviolet ray curable material on the target substrate (S100), selectively curing the preliminary resin layer formed of the ultraviolet ray curable material (S200), heating the target substrate and the preliminary resin layer (S300), and completely curing the preliminary resin layer S400. Hereinafter, each step (S100, S200, S300, and S400) will be described in detail.

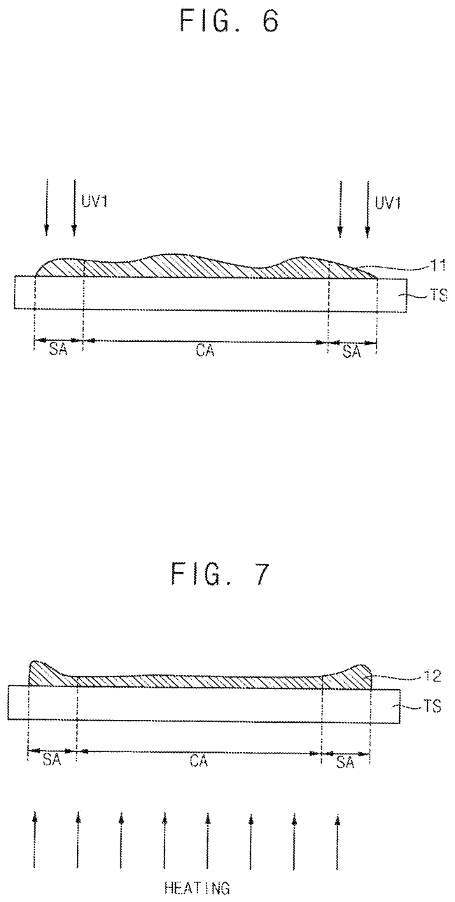

Referring to FIGS. 4 and 5, the ultraviolet ray curable material that reacts to ultraviolet rays may be selectively applied (S100) on the target substrate TS. Accordingly, a first preliminary resin layer (e.g., a first preliminary resin layer 11 of FIG. 6) including the ultraviolet ray curable material may be formed on the target substrate TS. For example, the ultraviolet ray curable material may include an optically transparent resin. However, the material of the ultraviolet ray curable material is not limited thereto.

In an embodiment, at least one method of inkjet, dispenser, and screen printing may be used as a method of applying the ultraviolet ray curable material on the target substrate TS. However, the disclosure is not limited thereto, and the ultraviolet ray curable material may be applied on the target substrate TS through various methods.

Referring to FIGS. 4, 6, and 7, as described above, the first preliminary resin layer 11 including the ultraviolet ray curable material may be formed on the target substrate TS. For example, the first preliminary resin layer 11 may have an uneven upper surface. For example, the first preliminary resin layer 11 may not have a flat upper surface.

The first preliminary resin layer 11 may be divided into a central area CA and a peripheral area SA. The peripheral area SA may be positioned adjacent to the central area CA. For example, the peripheral area SA may surround the central area CA.

First, as described with reference to FIG. 1, the data of the digital ultraviolet ray image of the first ultraviolet rays UV1, the first data of the irradiation time of the first ultraviolet rays UV1, and the second data of the amount of light of the first ultraviolet rays UV1 may be generated.

At least a portion of an entire area of the first preliminary resin layer 11 formed of the ultraviolet ray curable material may be irradiated with the first ultraviolet rays UV1 whose shape and amount of light are adjusted to selectively cure the first preliminary resin layer 11. Specifically, the first preliminary resin layer 11 may be selectively cured by adjusting the shape and amount of light of the first ultraviolet rays UV1 based on the data of the digital ultraviolet image of the first ultraviolet rays UV1, the first data of the irradiation time of the first ultraviolet rays UV1, and the second data of the amount of light of the first ultraviolet rays UV1.

In an embodiment, at least a portion of the peripheral area SA of the first preliminary resin layer 11 may be cured by irradiating the first ultraviolet rays UV1 whose shape and amount of light are adjusted. For example, the first preliminary resin layer 11 may be selectively cured (S200) by irradiating the first ultraviolet rays UV1 whose shape and amount of light are adjusted to the first preliminary resin layer 11. In other words, the central area CA of the first preliminary resin layer 11 may not be cured, and only the peripheral area SA of the first preliminary resin layer 11 may be cured. However, the disclosure is not limited thereto. For example, at least a portion of the central area CA of the first preliminary resin layer 11 may be cured by irradiating the first ultraviolet rays UV1 whose shape and amount of light are adjusted.

The first preliminary resin layer 11 may be selectively cured by the first ultraviolet rays UV1 to form a first preliminary resin layer 12. The first preliminary resin layer 12 may have a flat upper surface in the central area CA and the first preliminary resin layer 12 may protrude relatively compared to other portions in the peripheral area SA. However, the disclosure is not limited thereto, and the first preliminary resin layer 12 may have various cross-sectional shapes according to the irradiation position of the first ultraviolet rays UV1 whose shape and amount of light are adjusted.

After the first preliminary resin layer 12 is formed (i.e., after the first preliminary resin layer 11 is selectively cured), the target substrate TS and the first preliminary resin layer 12 may be heated (S300). Accordingly, the first preliminary resin layer 12 may be subjected to aging process. As the viscosity of the first preliminary resin layer 12 decreases and planarization progresses, mura of the first preliminary resin layer 12 may be removed. In another embodiment, heating the target substrate TS and the first preliminary resin layer 12 (S300) may be omitted.

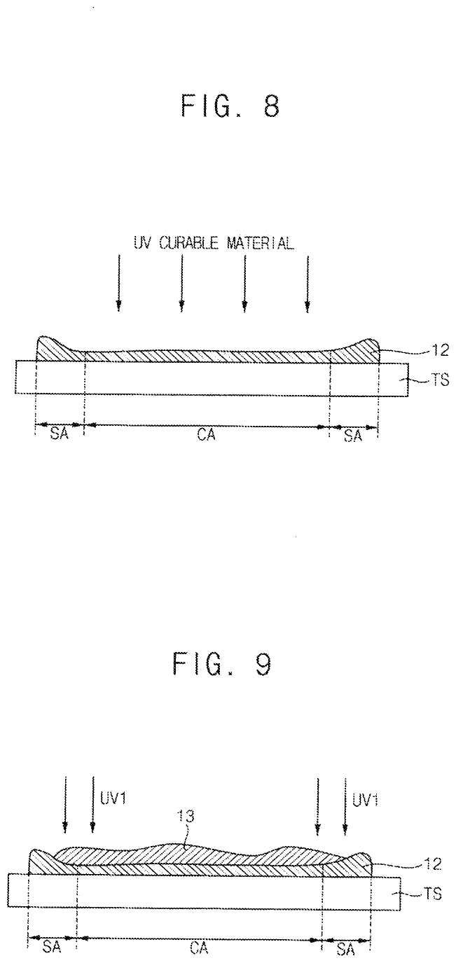

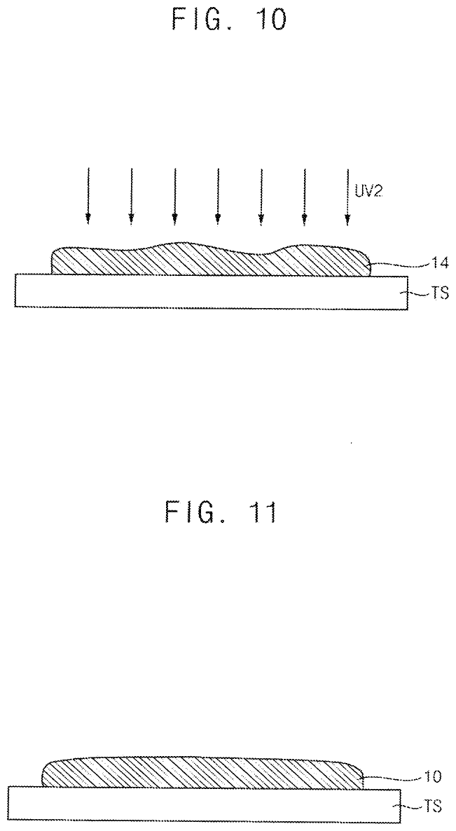

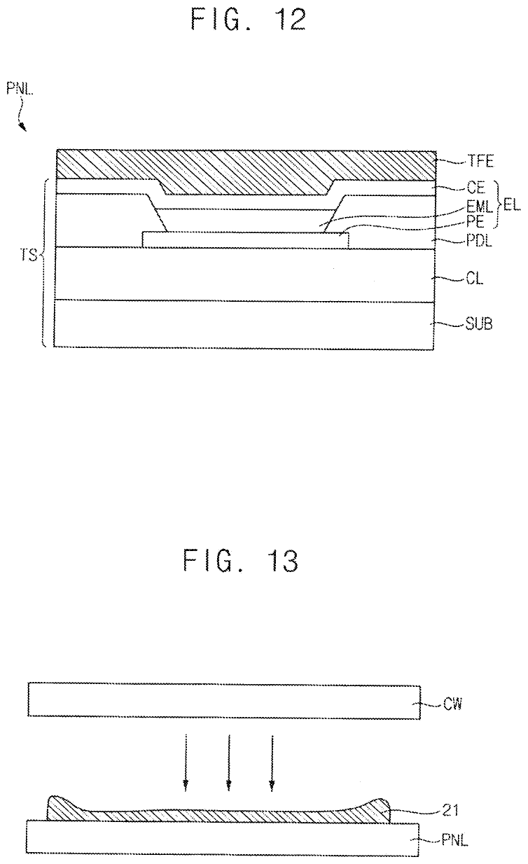

Referring to FIGS. 4 and 8, the ultraviolet ray curable material that reacts to ultraviolet rays may be selectively applied on the first preliminary resin layer 12. For example, the ultraviolet ray curable material may be applied twice on the target substrate TS. Accordingly, a second preliminary resin layer (e.g., a second preliminary resin layer 13 of FIG. 9) including the ultraviolet ray curable material may be formed on the first preliminary resin layer 12. However, the disclosure is not limited thereto, and the ultraviolet ray curable material may be applied once or three times or more on the target substrate TS. A resin layer (e.g., the resin layer 10 of FIG. 11) having a desired thickness may be formed by adjusting the number of times of application of the ultraviolet ray curable material.

Referring to FIGS. 4 and 9, as described above, the ultraviolet ray curable material may be selectively applied on the first preliminary resin layer 12 to form the second preliminary resin layer 13. Accordingly, the first preliminary resin layer 12 and the second preliminary resin layer 13 may be mixed to form a preliminary resin layer (e.g., a preliminary resin layer 14 of FIG. 10).

At least a portion of the entire area of the preliminary resin layer may be irradiated with first ultraviolet rays UV1. Accordingly, the preliminary resin layer may be selectively cured.

Referring to FIGS. 4, 10, 11, and 12, the entire area of the preliminary resin layer 14 may be irradiated with the second ultraviolet rays UV2. Accordingly, the preliminary resin layer 14 may be completely cured (S400). The second ultraviolet rays UV2 may have a relatively large amount of light. For example, the amount of light of the second ultraviolet rays UV2 may be greater than the amount of light of the first ultraviolet light (e.g., the first ultraviolet rays UV1 of FIG. 6) whose shape and amount of light are adjusted.

The preliminary resin layer 14 may be completely cured by the second ultraviolet rays UV2 to form the resin layer 10. The resin layer 10 may have a substantially flat upper surface. As described above, the target substrate TS may be a substrate for a display panel. The target substrate TS may include some of the components of the display panel PNL displaying an image. For example, the target substrate TS may include a base substrate SUB, a circuit layer CL, a pixel defining layer PDL, and a light emitting element EL. Hereinafter, components of the target substrate TS will be described in detail.

The base substrate SUB may include a transparent material or an opaque material. The base substrate SUB may be formed of a transparent resin substrate. Examples of the transparent resin substrate may include polyimide substrates and the like. The base substrate SUB may include a first organic layer, a first barrier layer, and a second organic layer. In another embodiment, the base substrate SUB may include a quartz substrate, a synthetic quartz substrate, a calcium fluoride substrate, an F-doped quartz substrate, soda-lime glass substrate, a non-alkali glass substrate, and the like. These may be used alone or in combination with each other.

The circuit layer CL may be disposed on the base substrate SUB. The circuit layer CL may provide signals and voltages for the light emitting element EL to emit light to the light emitting element EL. For example, the circuit layer CL may include a transistor, a conductive layer, an insulating layer, and the like.

The pixel electrode PE may be disposed on the circuit layer CL. The pixel electrode PE may receive the signals and the voltages from the circuit layer CL. For example, the pixel electrode PE may include a metal, an alloy, a metal nitride, a conductive metal oxide, a transparent conductive material, and the like. These may be used alone or in combination with each other. For example, the pixel electrode PE may be an anode electrode. In another embodiment, the pixel electrode PE may be a cathode electrode.

The pixel defining layer PDL may be disposed on the circuit layer CL and the pixel electrode PE. The pixel defining layer PDL may have an opening exposing a portion of the pixel electrode PE. The pixel defining layer PDL may include an organic material or an inorganic material. In an embodiment, the pixel defining layer PDL may include an organic material. Examples of the organic material that can be used as the pixel-defining layer PDL may include photoresist, polyacrylic resin, polyimide-based resin, polyamide-based resin, siloxane-based resin, acrylic resin, epoxy-based resin, and the like. These may be used alone or in combination with each other.

The light emitting layer EML may be disposed on the pixel electrode PE. Specifically, the light emitting layer EML may be disposed in the opening of the pixel defining layer PDL. The light emitting layer EML may include materials for emitting light. For example, the light emitting layer EML may include an organic light emitting material or an inorganic light emitting material.

The common electrode CE may be disposed on the pixel defining layer PDL and the emission layer EML. For example, the common electrode CE may include a metal, an alloy, a metal nitride, a conductive metal oxide, a transparent conductive material, and the like. These may be used alone or in combination with each other. For example, the common electrode CE may be a cathode electrode. In another embodiment, the common electrode CE may be an anode electrode.

Accordingly, the light emitting element EL including the pixel electrode PE, the light emitting layer EML, and the common electrode CE may be disposed on the base substrate SUB.

The thin film encapsulation layer TFE may be disposed on the common electrode CE. The thin film encapsulation layer TFE may protect the light emitting element EL from external oxygen and moisture. For example, the thin film encapsulation layer TFE may include at least one inorganic layer and at least one organic layer. In one embodiment, the resin layer 10 illustrated in FIG. 11 may be used as the thin film encapsulation layer TFE.

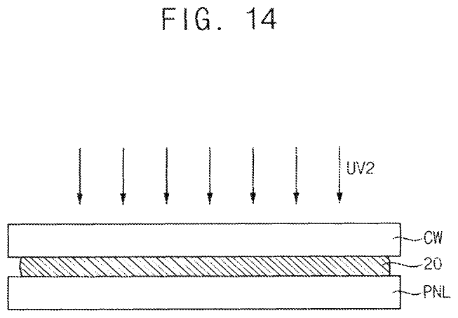

FIGS. 13 and 14 are cross-sectional views schematically illustrating another example of a method of forming the resin layer of FIG. 4. Hereinafter, descriptions overlapping with the method of forming the resin layer described with reference to FIGS. 4, 5, 6, 7, 8, 9, 10, 11, and 12 will be omitted or simplified.

Referring to FIGS. 7 and 13, a preliminary resin layer 21 including the ultraviolet ray curable material that reacts to ultraviolet rays may be formed on the target substrate TS. The preliminary resin layer 21 illustrated in FIG. 13 may be substantially the same as the preliminary resin layer 12 illustrated in FIG. 7.

The cover window CW may be positioned on the preliminary resin layer 21. Specifically, the cover window CW may be seated on the preliminary resin layer 21 so that the cover window CW is bonded to the target substrate TS. The cover window CW may protect the display panel (e.g., the display panel PNL of FIG. 12) from external impact. The cover window CW may include a transparent material. For example, the cover window CW may include a transparent material such as glass or plastic.

Referring to FIGS. 13 and 14, the preliminary resin layer 21 may be irradiated with the second ultraviolet rays UV2. The preliminary resin layer 21 may be completely cured by irradiating the second ultraviolet ray UV2 to the preliminary resin layer 21. Accordingly, the preliminary resin layer 21 may be completely cured to form the resin layer 20. The resin layer 20 may serve as an adhesive layer to bond the target substrate TS and the cover window CW.

As described above, the resin layer 10 formed through FIGS. 4, 5, 6, 7, 8, 9, 10, and 11 may be used as the thin film encapsulation layer TFE of the display panel PNL, and the resin layer 20 formed through FIGS. 4, 5, 6, 7, 13, and 14 may be used as an adhesive layer to bond the target substrate TS and the cover window CW. However, the disclosure is not limited thereto, and the resin layers 10 and 20 formed through FIGS. 4, 5, 6, 7, 8, 9, 10, 11, 12, 13, and 14 may be used in various fields.

Referring back to FIGS. 4, 5, 6, 7, 8, 9, 10, 11, 12, 13, and 14, the method of forming the resin layer according to an embodiment of the disclosure, both selectively applying the ultraviolet ray curable material on the target substrate TS and selectively curing a preliminary resin layer including the ultraviolet ray curable material applied on the target substrate TS may be applied. For example, selectively curing the preliminary resin layer may be added before completely curing the preliminary resin layer. Accordingly, a profile of a cross section of the resin layer 10 and 20 formed by curing the preliminary resin layer including the ultraviolet ray curable material may be adjusted. A uniformity of the resin layer 10 and 20 may be controlled, and unevenness of the resin layer 10 and 20 may be improved.

The disclosure can be applied to a process of manufacturing various display devices. For example, the disclosure can be applied to a process for manufacturing high-resolution smartphones, mobile phones, smart pads, smart watches, tablet PCs, vehicle navigation systems, televisions, computer monitors, laptops, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the disclosure. Accordingly, all such modifications are intended to be included within the scope of the disclosure. Therefore, it is to be understood that the foregoing is illustrative of various embodiments and is not to be construed as limited to the specific embodiments disclosed, and that modifications to the disclosed embodiments, as well as other embodiments, are intended to be included within the scope of the disclosure.

What is claimed is:

1. A method for forming a resin layer, the method comprising:
selectively applying an ultraviolet ray curable material that reacts to ultraviolet rays on a target substrate;
selectively curing a preliminary resin layer by irradiating at least a portion of an entire area of the preliminary resin layer formed of the ultraviolet ray curable material with first ultraviolet rays whose shape and amount of light are adjusted; and
completely curing the preliminary resin layer by irradiating second ultraviolet rays having a different amount of light from the first ultraviolet rays whose shape and amount of light are adjusted.

2. The method of claim 1, wherein the ultraviolet ray curable material includes an optical clear resin (“OCR”).

3. The method of claim 1, wherein
the preliminary resin layer is divided into a central area and a peripheral area adjacent to the central area, and
in the selectively curing of the preliminary resin layer, at least a portion of the peripheral area of the preliminary resin layer is selectively cured.

4. The method of claim 1, further comprising:
generating data of a digital ultraviolet ray image of the first ultraviolet ray, first data of an irradiation time of the first ultraviolet rays, and second data of the amount of light of the first ultraviolet rays before selectively curing the preliminary resin layer.

5. The method of claim 4, wherein in the selectively curing of the preliminary resin layer, the preliminary resin layer is selectively cured by adjusting the shape and amount of light of the first ultraviolet rays based on the data, the first data, and the second data.

6. The method of claim 4, wherein at least a portion of the digital ultraviolet ray image includes at least one of a 1-bit pattern shape, an 8-bit gray scale shape, a comb shape, a random dot form, and a mosaic shape.

7. The method of claim 6, wherein in the selectively curing of the preliminary resin layer, a portion of the preliminary resin layer corresponding to the at least the portion of the digital ultraviolet ray image is cured.

8. The method of claim 1, further comprising:
heating the target substrate and the preliminary resin layer after selectively curing the preliminary resin layer.

9. The method of claim 1, wherein in the selectively applying of the ultraviolet ray curable material, at least one of inkjet, dispenser, and screen printing is used.

10. The method of claim 1, wherein the amount of light of the second ultraviolet rays is greater than the amount of light of the first ultraviolet rays whose shape and amount of light are adjusted.

11. The method of claim 1, wherein the target substrate is a substrate for a display device.

12. An apparatus for forming a resin layer comprising:
a transfer stage that transfers a target substrate;
a printing part that selectively applies an ultraviolet ray curable material that reacts to ultraviolet rays on the target substrate;
a first light source that emits first ultraviolet rays;
a digital light source processing part that adjusts shape an amount of light of the first ultraviolet rays and selectively cures a preliminary resin layer by irradiating at least a portion of an entire area of the preliminary resin layer formed of the ultraviolet ray curable material with the first ultraviolet rays whose shape and amount of light are adjusted; and
a second light source that irradiates the preliminary resin layer with second ultraviolet rays having a different amount of light from the first ultraviolet rays whose shape and amount of light are adjusted.

13. The apparatus for forming the resin layer of claim 12, wherein the printing part includes at least one of an inkjet printing apparatus, a dispenser apparatus and a screen printing apparatus.

14. The apparatus for forming the resin layer of claim 12, wherein the ultraviolet ray curable material includes an optical clear resin.

15. The apparatus for forming the resin layer of claim 12, wherein the digital light source processing part includes:
a mirror that reflects the first ultraviolet rays emitted from the first light source;
a first lens that transmits the first ultraviolet rays reflected by the mirror;
a digital light source processing element that selectively reflects the first ultraviolet rays transmitted by the first lens; and
a second lens that transmits the first ultraviolet rays whose shape and amount of light area adjusted by the digital light source processing element.

16. The apparatus for forming the resin layer of claim 15, wherein the first lens is an illumination lens and the second lens is a projection lens.

17. The apparatus for forming the resin layer of claim 12, wherein the amount of light of the second ultraviolet rays is greater than the amount of light of the first ultraviolet rays whose shape and amount of light are adjusted.

18. The apparatus for forming the resin layer of claim 12, further comprising:
a transfer stage part that generates a position pulse signal;
an external trigger part that generates a trigger signal based on the position pulse signal;
an operation part that generates data of a digital ultraviolet ray image of the first ultraviolet rays and provides the data to the digital light source processing part, and generates first data of an irradiation time of the first ultraviolet rays and second data of the amount of light of the first ultraviolet rays; and
a light source controller that converts the trigger signal, the first data, and the second data into current impulses and provides the current impulses to the first light source.

19. The apparatus for forming the resin layer of claim 18, wherein the digital light source processing part selectively cures the preliminary resin layer by adjusting the shape and amount of light of the first ultraviolet rays based on the data, the first data, and the second data.

20. The apparatus for forming the resin layer of claim 18, wherein at least a portion of the digital ultraviolet ray image includes at least one of a 1-bit pattern shape, an 8-bit gray scale shape, a comb shape, a random dot shape, and a mosaic shape.

21. The apparatus for forming the resin layer of claim 20, wherein the digital light source processing part cures a portion of the preliminary resin layer corresponding to the at least the portion of the digital ultraviolet image.

22. The apparatus for forming the resin layer of claim 12, wherein the target substrate is a substrate for a display device.
